(19) United States
(12) Patent Application Publication
(10) Pub. No.: US 2011/0014772 A1
(43) Pub. Date: Jan. 20, 2011

(54) ALIGNING METHOD OF PATTERNED ELECTRODE IN A SELECTIVE EMITTER STRUCTURE

(76) Inventor: Huai-Tsung Chen, Tainan (TW)

Correspondence Address: NORTH AMERICA INTELLECTUAL PROPERTY CORPORATION, P.O. BOX 506, MERRIFIELD, VA, 22116, US

(21) Appl. No.: 12/549,358

(22) Filed: Aug. 28, 2009

(30) Foreign Application Priority Data
Jul. 20, 2009 (TW) 098124408

(51) Int. Cl. H01L 21/71

(52) U.S. Cl. 438/401; 438/57; 257/E21.536

(57) ABSTRACT

An aligning method of patterned electrode in a selective emitter structure includes the following steps. A substrate is provided. A barrier layer is then formed on the substrate. The barrier layer is patterned, and thus the substrate is partially exposed to form a patterned electrode region. Thereafter, the surface property of the substrate located in the patterned electrode region is changed, so as to form a visible patterned mark. Subsequently, the barrier layer is removed, and the visible patterned mark is used as alignment mark.

### BACKGROUND OF THE INVENTION

1. Field of the Invention

The present invention relates to an aligning method of patterned electrode in a selective emitter structure, and more particularly, to a method of forming a patterned electrode in a selective emitter structure, which achieves highly accurate alignment effect by referring to an alignment mark formed on the substrate surface.

2. Description of the Prior Art

The power generation efficiency of solar cell (solar battery) is mainly decided by the photoelectric conversion efficiency, which may be improved based on modifying the following three factors. First, improvement of light absorption ability. The free electron-hole pairs may be generated in the light absorption layer of solar cell when exposed under sunlight due to photovoltaic effect. When the solar cell has higher light absorption ability, more free electron-hole pairs may be generated, which therefore creates larger photo current. Second, reduction of recombination of electron-hole pairs. The recombination of electron-hole pairs causes loss of energy, and factors that causes the recombination includes: the dangling bond existing between grain boundary, and the internal defect in solar cell. Third, reduction of contact resistance. The contact resistance between the metal electrode and the semiconductor layer of solar cell may be reduced by virtue of forming heavy doping e.g. increasing dopants in the semiconductor layer. The heavy doping, however, will increase the probability of recombination of electron-hole pairs.

Currently, using selective diffusion technique to reduce the contact resistance has been developed in high efficiency solar cell industry to improve the photoelectric conversion efficiency. The method of selective diffusion is achieved by forming selective emitter structure, which forms patterned heavily doping region between the metal electrode and the semiconductor layer, but forms lightly doping regions in other regions of the semiconductor layer. Accordingly, the contact resistance can be reduced without increasing the probability of recombination of electron-hole pairs. In the conventional fabrication process of selective emitter structure, the location of the heavily doping region to be formed is defined by a mask pattern defined by photolithographic process, and the heavily doping region is then formed in the exposed region by diffusion technique. The photolithographic process, nevertheless, is complex and expensive. In addition, the trouble of aligning exists between the heavily doping region and the patterned electrode in the convention fabrication process of selective emitter structure. However, the photoelectric conversion efficiency of solar cell is adversely affected when the contact resistance is rising due to the alignment between the heavily doping region and the patterned electrode.

### SUMMARY OF THE INVENTION

It is therefore one of the objective of the present invention to provide an aligning method of patterned electrode in a selective emitter structure to address the misalignment issue in conventional method of forming patterned electrode in the selective emitter structure.

According to the present invention, an aligning method of patterned electrode in a selective emitter structure is provided. The method includes the following steps. First, a substrate is provided. Then, a barrier layer is formed on the substrate, and the barrier layer is patterned to partially expose the substrate to form a patterned electrode region. Subsequently, a surface property of the substrate of the patterned electrode region is changed to form a visible patterned mark. Thereafter, the barrier layer is removed, and the visible patterned mark is used as an alignment mark.

According to the present invention, an aligning method of patterned electrode in a selective emitter structure of a solar cell is further provided. The method includes the following steps. A substrate is provided. Then, a barrier layer is formed on the substrate, and the barrier layer is patterned to partially expose the substrate to form a patterned electrode region. Subsequently, a surface property of the substrate of the patterned electrode region is changed to form a visible patterned mark. Thereafter, the barrier layer is removed, and the visible patterned mark is used as an alignment mark to form a patterned electrode on a surface of the substrate in the patterned electrode region.

According to the method of the present invention, a visible patterned mark is formed on the surface of the substrate in the patterned electrode region in advance, and thus the patterned electrode formed subsequently can be precisely aligned by referring to the visible patterned mark as an alignment mark.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 are schematic diagrams illustrating an aligning method of patterned electrode in a selective emitter structure of a solar cell in accordance with a preferred embodiment of the present invention.

### DETAILED DESCRIPTION

To provide a better understanding of the presented invention, a preferred embodiment will be explained in details. The preferred embodiment of the present invention is illustrated in the accompanying drawings with numbered elements. But the application of the present invention is not limited to the preferred embodiment.

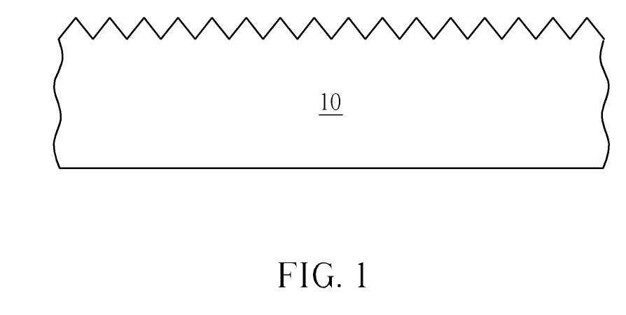

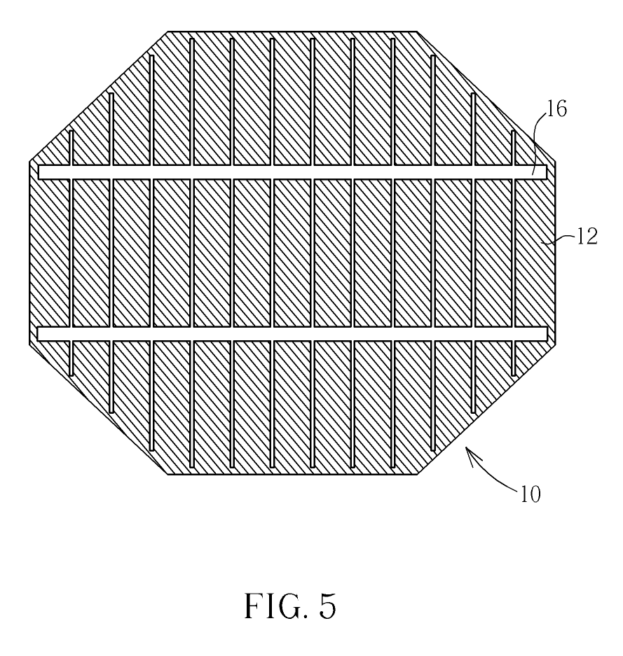

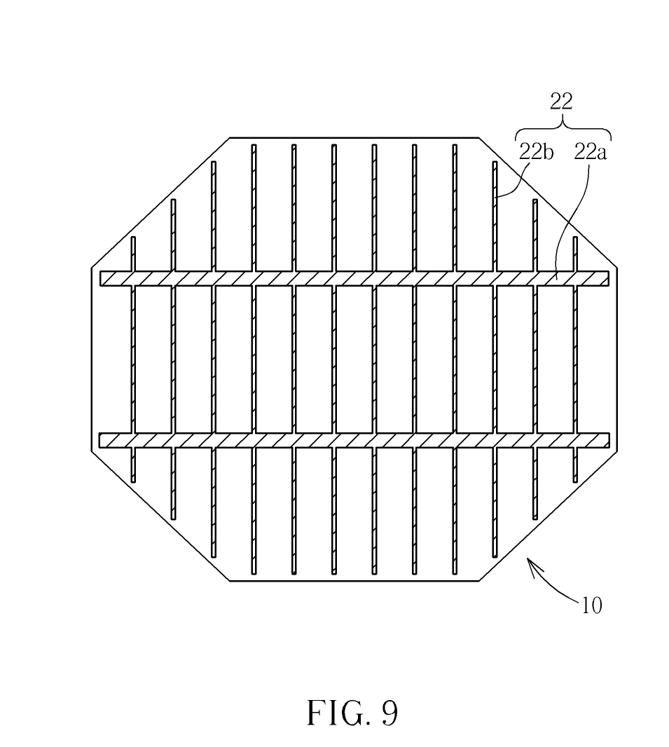

Please refer to FIGS. 1-9. FIGS. 1-9 are schematic diagrams illustrating an aligning method of patterned electrode in a selective emitter structure of a solar cell in accordance with a preferred embodiment of the present invention. To clearly illustrate the characteristic features of the present invention, FIGS. 1-4 and FIGS. 6-8 are cross-sectional views, while FIGS. 5 and 9 are top views. In addition, the aligning method of patterned electrode in a selective emitter structure of a solar cell is embodied to exemplarily elaborate the present invention, but the application of the present invention is not limited to the preferred embodiment. As shown in FIG. 1, a substrate 10 is provided. In this embodiment, the substrate 10 is a semiconductor layer, but not limited. Then, a texturing treatment is carried out on the surface of the substrate 10. The textured surface reduces the reflection of incident light, and therefore the photoelectric conversion efficiency may be improved due to the increase of incident light beams.

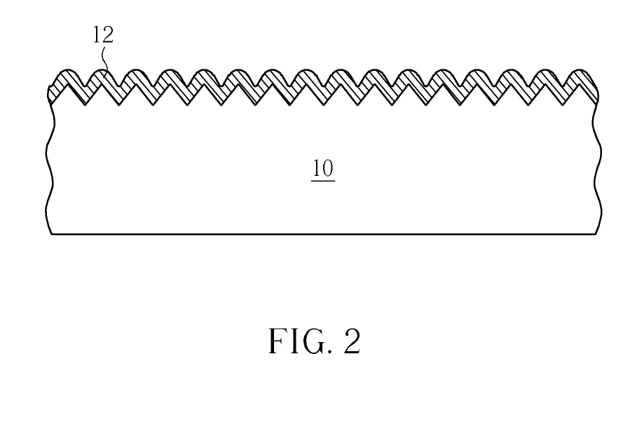

As shown in FIG. 2, a barrier layer 12 is formed on the substrate 10. Since the selective emitter structure of solar cell is used as an example in the present invention, the barrier layer 12 is a diffusion barrier layer which may be formed by various thin film formation techniques.

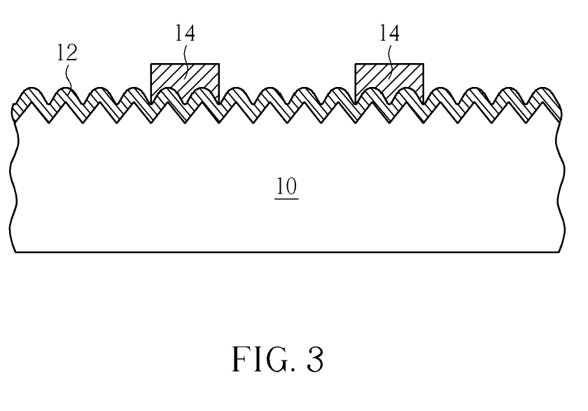

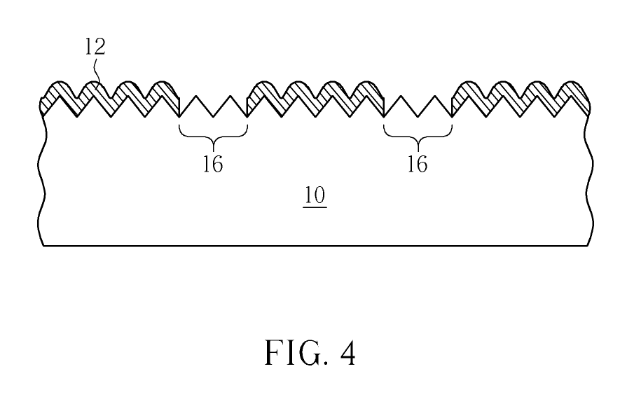

Subsequently, the barrier layer 12 is patterned to partially expose the surface of the substrate 10, which forms a pattern electrode region. In this embodiment, the method of patterning the barrier layer 12 includes the following steps. First, as shown in FIG. 3, a patterned etching material 14 is formed on the barrier layer 12 for defining the location of patterned electrode. The patterned etching material 14 selectively etches off part of the barrier layer 12 downwardly to partially expose the surface of the substrate 10. As shown in FIGS. 4-5, the patterned etching material 14 is removed to expose the patterned electrode region 16 of the substrate 10.

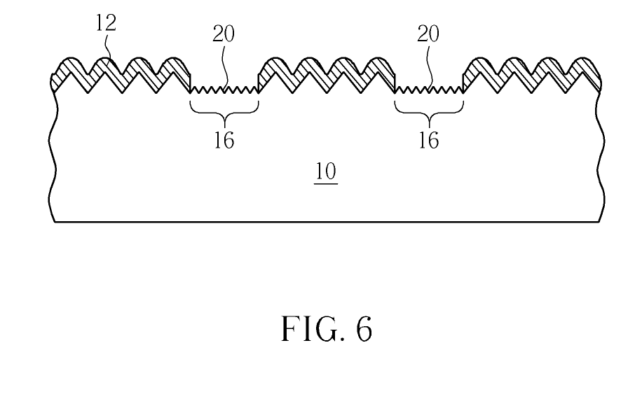

As shown in FIG. 6, the surface property of the substrate 10 in the patterned electrode region 16 is changed to form a visible patterned mark 20. In this embodiment, the surface property of the substrate 10 in the patterned electrode region 16 denotes the surface roughness of the substrate 10. By virtue of changing the surface roughness of the substrate 10 in the patterned electrode region 16, the optical reflectivity of the substrate 10 in the patterned electrode region 16 changes accordingly. In comparison with other regions of the substrate 10, the different optical reflectivity renders the patterned electrode region 16 a visible patterned mark 20, which may serve as an alignment mark. As illustrated in FIG. 6, the optical reflectivity of the substrate 10 in the patterned electrode region 16 is distinct from other regions of the substrate 10, and therefore the visible patterned mark 20 can be used as alignment mark. It is noted that the surface property is not limited to the surface roughness i.e. the optical reflectivity. Therefore, the visible patterned mark 20 may be formed by changing other surface property of the substrate 10 in the patterned electrode region 16.

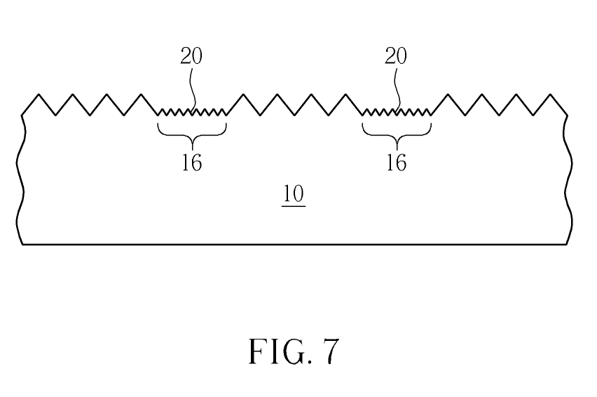

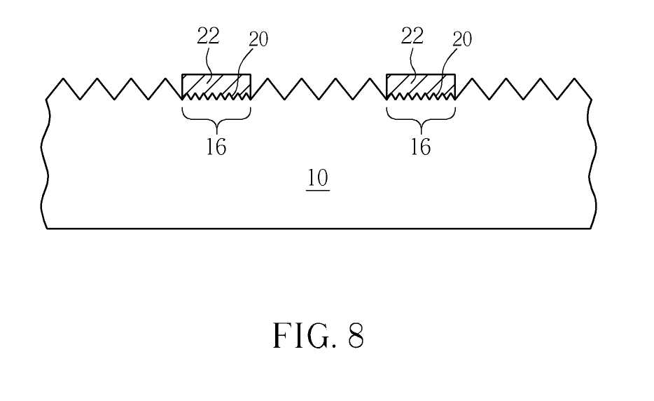

As shown in FIG. 7, the barrier layer 12 is then removed from the surface of the substrate 10. As shown in FIGS. 8-9, the visible patterned mark 20 is used as alignment mark, and a patterned electrode 22 is formed on the patterned electrode region 16 of the substrate 10 by referring the visible patterned mark 20. In this embodiment, the patterned electrode 22 is formed by a screen printing process, but the application of the present invention is not limited to the preferred embodiment. In addition, the patterned electrode 22 includes bus bars 22a that have larger line width, and fingers 22b that have smaller line width, but the pattern of the patterned electrode 22 is not limited.

In summary, the aligning method of patterned electrode in a selective emitter structure of a solar cell forms a visible patterned mark on the surface of the substrate in the patterned electrode region in advance, and thus the patterned electrode formed subsequently can be precisely aligned by referring to the visible patterned mark as an alignment mark.

Those skilled in the art will readily observe that numerous modifications and alterations of the device and method may be made while retaining the teachings of the invention.

What is claimed is:

1. An aligning method of patterned electrode in a selective emitter structure, comprising:
providing a substrate;
forming a barrier layer on the substrate, and patterning the barrier layer to partially expose the substrate to form a patterned electrode region;
changing a surface property of the substrate of the patterned electrode region to form a visible patterned mark;
removing the barrier layer; and
using the visible patterned mark as an alignment mark.

2. The aligning method of claim 1, wherein patterning the barrier layer comprises steps of:
forming a patterned etching material on the barrier layer;
using the patterned etching material to selectively etch off part of the barrier layer to partially expose the substrate; and
removing the patterned etching material.

3. The aligning method of claim 1, wherein changing the surface property of the substrate of the patterned electrode region comprises changing an optical reflectivity of the substrate of the patterned electrode region.

4. The aligning method of claim 1, wherein the barrier layer comprises a diffusion barrier layer.

5. An aligning method of patterned electrode in a selective emitter structure of a solar cell, comprising:
providing a substrate;
forming a barrier layer on the substrate, and patterning the barrier layer to partially expose the substrate to form a patterned electrode region;
changing a surface property of the substrate of the patterned electrode region to form a visible patterned mark;
removing the barrier layer; and
using the visible patterned mark as an alignment mark to form a patterned electrode on a surface of the substrate in the patterned electrode region.

6. The aligning method of claim 5, wherein patterning the barrier layer comprises steps of:
forming a patterned etching material on the barrier layer;
using the patterned etching material to selectively etch off part of the barrier layer to partially expose the substrate; and
removing the patterned etching material.

7. The aligning method of claim 5, wherein changing the surface property of the substrate of the patterned electrode region comprises changing an optical reflectivity of the substrate of the patterned electrode region.

8. The aligning method of claim 5, wherein the patterned electrode is formed by a screen printing process.

9. The aligning method of claim 5, wherein the barrier layer comprises a diffusion barrier layer.

10. The aligning method of claim 5, further comprising performing a texturing treatment on the surface of the substrate.
